(19) United States
(12) Patent Application Publication
(10) Pub. No.: US 2006/0039433 A1
(43) Pub. Date: Feb. 23, 2006

(54) Silicon nanocrystal/erbium doped waveguide (SNEW) laser

(76) Inventor: John T. Simpson, Clinton, TN (US)

Correspondence Address: AKERMAN SENTERFITT, P.O. BOX 3188, WEST PALM BEACH, FL, 33402-3188, US

(21) Appl. No.: 10/922,735

(22) Filed: Aug. 20, 2004

(51) Int. Cl. H01S 5/00

(52) U.S. Cl. 372/50.1

(57) ABSTRACT

A rare earth-doped solid-state integrated laser which includes an optical waveguide, and a laser cavity including at least one subwavelength mirror. The subwavelength mirror is disposed in or on the optical waveguide. The optical waveguide portion within the laser cavity includes active media comprising both a rare earth and semiconducting atoms or compounds. A structure for pumping the semiconducting semiconducting atoms or compounds is provided, such as electrodes sandwiching the active media wherein the semiconducting atoms or compounds transfer energy obtained from the pumping to the rare earth, thus permitting the laser to laze.

### STATEMENT REGARDING FEDERALLY SPONSORED RESEARCH OR DEVELOPMENT

The United States Government may have certain rights in this invention pursuant to Contract No. DE-AC05-00OR22725 between the United States Department of Energy and UT-Battelle, LLC.

### CROSS-REFERENCE TO RELATED APPLICATIONS

Not applicable.

### FIELD OF THE INVENTION

The invention relates to solid state lasers and optical amplifiers, more specifically optical waveguide cavity based lasers formed using subwavelength mirrors.

### BACKGROUND OF THE INVENTION

Integration of optical components within semiconductor microchips has been a goal for many years. Such integration could create new and improved devices. The main reason why this integration has not yet occurred is due to the lack of any small CMOS compatible laser sources. Current solid-state lasers generally use gain media of non-standard III-V (or II-VI) materials, such as GaAlAs formed in a multiple quantum well configuration. Such non-standard materials are difficult to fabricate and are highly incompatible with standard semiconductor microchip processes which are generally silicon-based.

A solid state laser suitable for integration with standard semiconductor microchip processes would be constructed from silicon-based materials, or at least be CMOS compatible, and would include a semiconductor process compatible optical waveguide material to facilitate energy transport. However, several challenges including lack of suitable mirrors have generally prevented fabrication of laser cavities within optical waveguides.

Optical gain has been observed in pumped optical fibers when the fibers are doped with various rare earth (RE) atoms or ions. The RE dopant erbium (Er) has the desirable feature of providing optical gain at a wavelength corresponding to a non-absorption spectral region of silica glass (a wavelength of about 1.54 μm). This wavelength is the current wavelength of choice for fiber optic communications.

A number of optical amplifiers based on Er have become commercially available over the last few years. A major drawback of Er doped amplifiers is their inability to be electronically pumped. Accordingly optical “flashlamp” pumping is required. Another drawback of conventional Er-based amplifiers is the small gain coefficient provided.

### SUMMARY OF INVENTION

A rare earth (RE)-doped solid-state integrated laser which includes an optical waveguide, and a laser cavity including at least one subwavelength mirror. The subwavelength mirror is disposed in or on the optical waveguide. The optical waveguide portion within the laser cavity includes active media comprising both a RE species and semiconducting atoms or compounds. A structure for pumping the semiconducting atoms or compounds is provided, wherein the semiconducting atoms or compounds transfer energy obtained from the pumping to the RE, providing population inversion in the RE, thus permitting the laser to laze.

The structure for pumping can comprise a pair of electrodes sandwiching the active media. The rare earth can comprise Er and the laser cavity can be resonant from 1.52 to 1.57 microns. The subwavelength mirror can comprise a first and a second subwavelength mirror, the first and second subwavelength mirror disposed on respective ends of the laser cavity. In one embodiment, the first and second subwavelength mirrors comprise subwavelength resonant gratings, each grating comprising a plurality of periodically spaced high refractive index features disposed in the waveguide, the high refractive index features providing a refractive index higher than the refractive provided by the waveguide material. In another embodiment, the first and second subwavelength mirrors comprise photonic crystals, each photonic crystal having a plurality of low refractive index features in the waveguide, the low refractive index lower than the refractive provided by the waveguide material. In another embodiment, the subwavelength mirror can comprise a single distributed feedback structure (DFB), wherein light in the laser cavity is channeled toward a center of the cavity.

The optical waveguide can comprise silicon dioxide. In one embodiment, the laser includes a photonic band edge structure (PBE) positioned between the first and the second subwavelength mirror.

The semiconducting atoms or compounds can comprise silicon nanocrystals. In a preferred embodiment, the laser is disposed on or embedded in a bulk substrate material. The optical waveguide can comprise an electro-optic material.

A method for forming a rare earth-doped solid-state integrated laser includes the steps of providing an optical waveguide, forming a laser cavity including at least one reflective subwavelength mirror disposed in or on the optical waveguide, and positioning a plurality of rare earth and semiconducting atoms or compounds in the cavity. The method can further comprise the step of forming a pair of electrodes, the electrodes sandwiching the rare earth and semiconducting atoms or compounds in the laser cavity. The semiconducting atoms or compounds can comprise a plurality of nanocrystals, and the method can further comprise the step of forming the plurality of nanocrystals, such as Si nanocrystals.

### BRIEF DESCRIPTION OF THE DRAWINGS

A fuller understanding of the present invention and the features and benefits thereof will be accomplished upon review of the following detailed description together with the accompanying drawings, in which:

FIG. 1(a) illustrates a perspective view of a prior art photonic crystal (PC) which includes a periodic array of holes.

FIG. 1(b) illustrates the spectral response of the PC in FIG. 1(a) demonstrating a broadband reflectance.

FIG. 2 illustrates a perspective view of a prior art subwavelength gating (SWG) having six posts.

FIG. 3(a) illustrates a cross sectional perspective view of an electrically pumped solid state RE-doped laser including a Distributed Bragg Reflector (DBR), according to an embodiment of the invention.

FIG. 3(b) illustrates a cross sectional perspective view of an electrically pumped solid state RE-doped laser including a pair of subwavelength resonant grating (SWG) mirrors, according to another embodiment of the invention. An inset below shows waveguide cavity details.

FIG. 4(a) illustrates a cross-sectional view of a solid state laser which combines subwavelength reflective mirrors with a photonic band edge structure (PBE) structure disposed between the subwavelength mirrors, the laser cavity including a waveguide having a plurality of embedded semiconducting nanocrystals and RE species, according to another embodiment of the invention.

FIG. 4(b) illustrates the energy distribution in the laser cavity of the laser shown in FIG. 4(a) during laser operation at a dielectric band edge wavelength.

FIG. 5(a) illustrates a cross-sectional view of a solid state laser having a pair of PBG subwavelength mirrors, the laser cavity including a waveguide having a plurality of embedded semiconducting nanocrystals and RE species, while FIG. 5(b) illustrates a top view of the same.

FIG. 6 illustrates a symmetrical optical waveguide structure formed using a top and bottom layer of cladding material to sandwich a layer of waveguide material having embedded semiconducting nanocrystals and RE species therein, according to an embodiment of the invention.

### DETAILED DESCRIPTION OF THE PREFERRED EMBODIMENTS

The present invention is related to U.S. patent application Ser. No. 10/315,578 ('578) filed on Dec. 10, 2002 entitled “NANOCRYSTAL WAVEGUIDE (NOW) LASER”, and is assigned to the same assignee as the present invention. '578 was published as published U.S. application No. 20040109483 on Jun. 10, 2004. '578 discloses a solid state laser including an optical waveguide and a laser cavity including at least one subwavelength mirror disposed in or on the optical waveguide. A plurality of semiconducting nanocrystals are disposed in the laser cavity. '578 is incorporated by reference into the current application in its entirety.

The present invention comprises a rare earth (RE)-doped solid-state integrated laser which includes an optical waveguide, and a laser cavity including at least one subwavelength mirror. The subwavelength mirror is disposed in or on the optical waveguide. The optical waveguide portion within the laser cavity includes active media comprising both an RE species and atomic or compound semiconducting nanocrystals. Although the semiconducting nanocrystals described herein are generally recognizable as being photoluminescent (PL) nanocrystals, the nanocrystals generally become non-photoluminescent in the presence of the REs in lasers according to the invention because the nanocrystals transfer their energy to the REs instead of photoluminescing. A structure for pumping the semiconducting atoms or compounds is also provided. Thus, the pumped semiconducting atoms or compounds non-radiatively transfer energy obtained from the pumping to the RE, permitting the laser to laze, thus increasing the RE optical gain. The integrated laser cavity is directly accessible to external influences, such as optical or electrical pumping.

Many REs are known emit in the infrared due to electronic transitions in unfilled 4 f shells once suitably excited. REs suitable for use with the invention function as an optical gain media by receiving energy from the semiconducting atoms or compounds, and as a result emitting light in the wavelength range of interest. As used herein, “light” means not only signals in the spectrum of visible light, but also signals in the full spectrum of frequencies typically handled by optical systems, including infrared wavelengths.

In a preferred embodiment, the RE comprises Er and the laser cavity is sized to be resonant at from 1.52 to 1.57 microns, such as 1.54 microns. In another embodiment, the RE comprises holmium (Ho) and the laser cavity is resonant from 2.06 to 2.10 microns, such as at 2.08 microns.

The subwavelength mirror can comprises a first and a second subwavelength mirror disposed on respective ends of the laser cavity. The subwavelength mirrors can be a photonic crystal (PC), a quarter-wave stack (QWS), or a subwavelength grating (SWG). Alternatively, a single distributed feedback structure (DFB) can be used, wherein the DFB channels light in the resonant laser cavity toward a center of cavity.

Details regarding the subwavelength effect can be found in '578 or in various publications. Details regarding PCs and sub-wavelength gratings (SWGs) will be described individually prior to describing the laser according to the invention. Details regarding the well known QWS will not be presented herein.

It is known that as the periodicity of a medium becomes comparable with the wavelength of electromagnetic waves traveling therethrough, the medium can begin to significantly inhibit the wave's propagation. A PC is one type of subwavelength optical structure that can be used for certain electromagnetic (EM) wave applications. PCs are composite periodic structures made up of two different dielectric materials. Both of the dielectric materials should be nearly transparent to electromagnetic radiation in the frequency range of interest. However, the composite periodic structure may not be transparent to the frequency range of interest, due to electromagnetic scattering at the interfaces between the two dielectric components. Intervals of prohibited frequencies are called photonic band gaps.

Relying on the subwavelength wave inhibition effect, PCs are two or three-dimensional periodic array structures in which the propagation of EM waves may be described by band structure types of dispersion relationships resulting from scattering at the interfaces between the two dielectric components. Waveguide dispersion is the term used to describe the process by which an electromagnetic signal is distorted by virtue of the dependence of its phase and group velocities on the geometric properties of the waveguide. These photonic band gap structures provide electromagnetic analogs to electron-wave behavior in crystals, with electron-wave concepts such as reciprocal space, Brillouin zones, dispersion relations, Bloch wave functions, Van Hove singularities and tunneling having electromagnetic counterparts in a PC.

PCs can be formed with added local interruptions in an otherwise periodic photonic crystal, thereby generating defect or cavity modes with discrete allowed frequencies within an otherwise forbidden photonic band gap range of frequencies. In a perfectly periodic photonic crystal, allowed photonic states are quantized, with band gaps having no allowed states between discrete allowed states. However, when a periodic array of features, such as holes, is introduced into a waveguide material to form a perfectly periodic photonic crystal, the wavevector k becomes quantized and limited to π/a, where a is the spatial period of the holes. In addition to putting a limit on wavevector values, the introduction of an array of holes in a waveguide has the effect of folding the dispersion relations (ωₙ(k)) of the strip waveguide and splitting the lowest-order mode to form two allowable guided modes. The splitting at the Brillouin zone edge is referred to as a band gap. The size of the band gap is determined by the relative dielectric constants of the waveguide material and the material filling the periodic structures, such as air in the case of holes. The larger the difference in relative dielectric constants, the wider the gap.

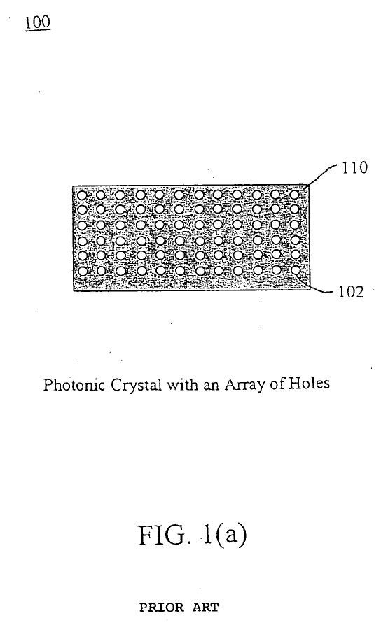

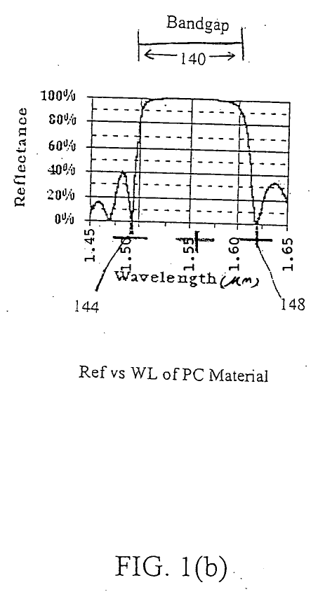

FIG. 1(a) shows a perspective view of a PC 100 formed from a 12×6 periodic array of features which comprise holes, each hole represented as 102. Holes 102 are disposed in a dielectric waveguide 110 and arranged in a periodic fashion with a substantially constant inter-hole spacing. Thus, no defect is included. Although holes 102 are shown in FIG. 1(a), holes 102 can be replaced by low refractive index features, the low refractive index being relative to the higher refractive index waveguide material.

FIG. 1(b) shows the reflective response of PC 100 shown in FIG. 1(a). PC 100 is seen to function as a broadband mirror in the band from about 1.50 μm to 1.60 μm. This band is referred to band gap 140, as wavelengths in this band are not transmitted by PC 100. FIG. 1(b) also reveals two band edges 144 and 148, band edges 144 and 148 being at wavelengths which are nearly 100% transmissive, the band edges located adjacent to the edges of band gap 140. In the embodiment where the low refractive index periodic features are holes, band edge 144 is referred to as the air band edge. Band edge 148 is referred to as the dielectric band edge. The dielectric band edge 148 will always be at a longer wavelength (i.e. lower frequency) as compared to the air band edge 144, or more generally at a longer wavelength relative to the low refractive index material band edge.

If PC 100 is operated at dielectric band edge 148, then the optical energy is concentrated within the high index dielectric waveguide region 110 which is disposed between holes 102. However, if PC 100 is operated at air band edge 144, the optical energy is concentrated within the low index holes 102.

If a defect is included into an otherwise periodic PC, an allowed photonic state can be created within the band gap. This state is analogous to a defect or impurity state in a semiconductor which introduces an energy level within the band gap of the semiconductor. A defect in the otherwise periodic PC structure is formed by incorporating a break in the periodicity of the PC structure. PC defects can take the form of a spacing variation using constant features, use features having a different size or shape, or use a different material. Introduction of a PC defect may result in the creation of a resonant wavelength within the band gap.

Subwavelength resonant gratings (SWGs) are a second type of subwavelength optical structure. Grating structures are generally known in the art to provide a method of dispersing incident electromagnetic wave energy. In particular, gratings comprising periodic elements have been used to diffract light incident on a grating created by periodic slits cut into a given material. When light is incident on the surface of a single diffraction grating, the light may be reflected (or backward diffracted) and/or transmitted (or forward diffracted) at angles that depend upon the periodicity of the grating relative to the wavelength of the incident light and the light's angle of incidence.

Optical wavelength may be defined as the wavelength of an EM wave in a given material and is equal to the wavelength of the wave in a vacuum divided by the material's refractive index. As the period of the grating approaches the optical wavelength of the incident radiation, the diffracted orders begin propagating at increasingly larger angles relative to the surface normal of the grating. Eventually, as the grating period is reduced and approaches the optical wavelength of the incident radiation, the angle of diffraction approaches 90 degrees, resulting in propagation of the radiation confined to the plane of the grating. This subwavelength condition effectively couples the fields of the incident radiation within the grating structure, a direction transverse to the surface normal of the grating provided the grating structure has a higher refractive index than the surrounding material and provides a mechanism to couple the diffracted energy into an orthogonal guided wave mode.

An example of the formation and use of a SWG is described in U.S. Pat. No. 6,035,089, by Grann, et. al (“Grann”), which is assigned to Lockheed Martin Energy Research Corporation, predecessor to the assignee of the current application. Grann describes a single SWG that uses periodically spaced high refractive index “posts” embedded in a lower refractive index dielectric waveguide material to form an extremely narrowband resonant reflector.

A SWG which functions as a zeroth order diffraction grating can be represented by an effectively uniform homogeneous material having an effective refractive index (n_{eff}). Under particular incident wave configurations, such as a substantially normal incident beam, and certain structural constraints, such as the refractive index of the medium surrounding the grating<refractive index of the waveguide<refractive index of the posts, a subwavelength structure may exhibit a resonance anomaly which results in a strong reflected beam over an extremely narrow bandwidth. If the incident radiation is not within the SWG resonant bandwidth, most of the energy of the incident beam will propagate through the grating in the form of a transmitted beam.

This resonance phenomenon occurs when electromagnetic radiation is trapped within the grating material due to total internal reflection. If this trapped radiation is coupled into the resonant mode of the SWG, the field will resonate and redirect substantially all of the electromagnetic energy backwards. This resonance effect results in a nearly total reflection of the incident field from the surface, which may be designed to be extremely sensitive to wavelength.

Grann's embedded grating structure results in minimal sideband reflections. Since Grann's resonant structure is buried within a waveguide, both the input and output regions of the grating share the same refractive index, resulting in minimal or no Fresnel reflection losses. Thus, reflection losses are minimized permitting operation as an extremely reflective resonant grating.

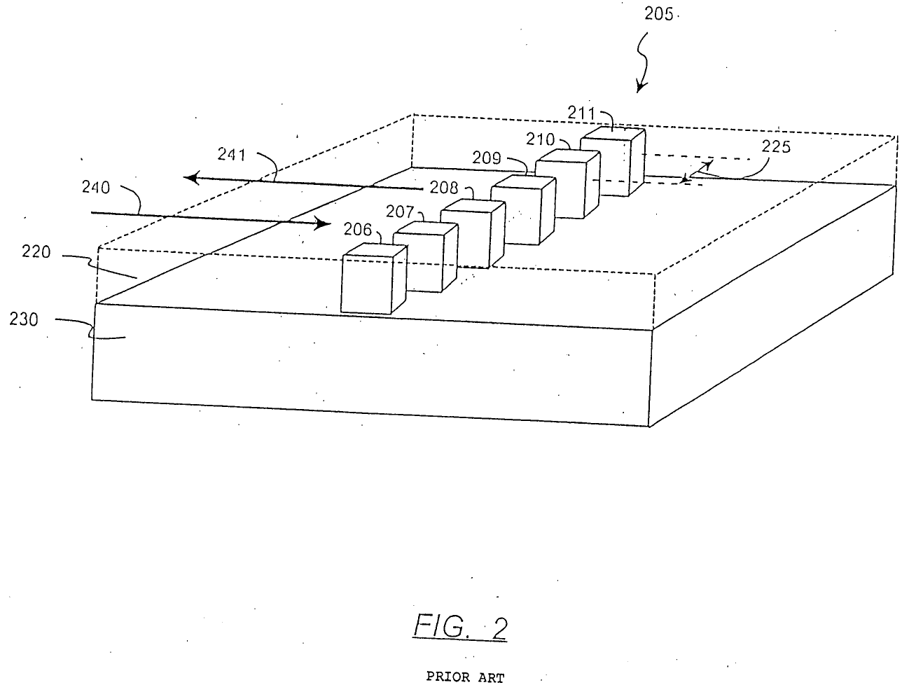

Referring to FIG. 2, a broadband resonant reflecting SWG 205 is shown which is formed from six high refractive index posts 206-211 in a waveguide material 220. Posts 206-211 are periodically spaced having a given post-to-post spacing called a grating period (T) 225. The refractive index of material comprising posts 206-211 should be greater than that of the waveguide material 220. Cladding layer 230 having a refractive index lower than both the waveguide material and post material may be used to physically support SWG 205. Cladding layer 230 may comprise several individual layers, each having somewhat different physical properties.

Six to ten (or possibly more) posts 206-211 are believed to be a minimum number for SWG 205 to function as a resonant reflector and would correspond to cavity width of three to five resonant wavelengths, since the grating period 225 is nominally one half of a resonant wavelength. Feature shapes also influence SWG 205 function. Shapes such as square, cylindrical and rectangular have demonstrated successful results. Other shapes are also possible. Grating period 225 should preferably be less than the incident wavelength divided by the waveguide index of refraction (i.e., λ₀/(n_{wg}). The specific grating period depends on the post index of refraction. The larger the post refractive index vs. waveguide refractive index, the smaller the ratio of wavelength to grating period 225.

Posts 206-211 may be arranged in a line or other arrangements which allow an approximately constant post-to-post spacing. For example, appropriately spaced posts may be placed along an arc having a given radius of curvature. This could be particularly advantageous for EM waves that had wavefronts with similar radii of curvatures.

Again referring to FIG. 2, an incident photon beam 240 may be applied to SWG 205. A portion of the incident beam 240 is reflected as photon beam 241. If a large percentage of incident beam 240 is reflected, SWG 205 is said to act as a mirror. If SWG 205 functions as a mirror over a wide range of wavelengths, SWG 205 may be said to be a broadband mirror. The reflective bandwidth of SWG 205 may be defined to be a range of wavelength values within the SWG 205 response which are within 3 dB of the SWG mirror's 205 peak reflective response. For example, if SWG 205 is fully reflective at a given center wavelength and a line is drawn at 70.71% (3 dB) below the peak reflectivity, a wavelength above and below the center wavelength will be cut. The difference between the wavelengths cut by the 3dB line may be defined to be equal to the SWG's 205 bandwidth.

SWG 205 may be designed to function as a broadband reflector through iterative solutions by varying SWG parameters. Software simulations are preferably used to solve Maxwell's equations applied to photons interacting with periodic embedded structures, such as SWG 205. This problem has been solved herein using “rigorous coupled wave equation” simulations. For example, GSOLVER™ grating simulation software produced by Grating Software Development Company, located in Allen, Tex., may be used to simulate photon interactions with SWG 205.

The grating variables involved in setting the spectral response of SWG 205 include the refractive index of the post 206-211 material, the refractive index of the waveguide 220 material, the grating period 225 and the fill factor, also referred to as the “duty cycle.” The fill factor or duty cycle is defined as the fraction of area within the grating region containing posts. Post 206-211, waveguide 220 and cladding material 230 are chosen such that the refractive index of the post 206-211 material exceeds the refractive index of the waveguide 220 material, and the waveguide 220 material exceeds the refractive index of the cladding material 230.

A desired center resonant wavelength λ₀ is then selected. The initial fill factor may be set at 50%, for example, when the width of individual post is equal to half of the grating period 225. The required grating period 225 to achieve a desired center resonant wavelength λ₀ may be estimated. The following equation below provides an estimate of the grating period (T) 225 required to achieve a resonant reflectance at a desired center resonant wavelength λ₀, given the waveguide 220 refractive index (n_{g}) and post 206-211 refractive index (n_{swg}).
T=3 λ₀/(n_{g}*n_{swg})

However, this equation is a simple “rule of thumb” and should only generally be used as a starting point. Since the actual interactions are quite complex, a fully vectorial solution using Maxwell's equation is suggested for most applications.

Using a rigorous coupled wave equation software package, such as GSOLVER™, SWG structures, such as 205, or optical resonators formed by combining two grating structures such as 205, may be simulated over a range of wavelengths and the resulting center resonance wavelength λ₀ determined. Once a grating period 225 is found that results in the desired center resonance reflectance wavelength λ₀, the simulation may proceed to increase the grating's bandwidth.

The reflective resonance bandwidth of SWG 205 may be changed by adjusting the post fill factor and the shape of the posts, or both the fill factor and post shape. As a preferred method, the post fill factor is first either increased or decreased, and the results simulated. This iterative method may be continued until the bandwidth is maximized, or at least acceptably wide for a given application. If the bandwidth is not broad enough, the bandwidth may be further changed by changing post shape. For example, in the case of square posts, rectangular posts may be substituted and results re-simulated.

The particular manufacturing process used for fabricating the SWG 205 should preferably be inexpensive and reproducible. Conveniently, the SWG 205 of the present invention can be fabricated using any standard integrated optics or electronic integrated circuit manufacturing method. Such methods use standard oxidation, deposition, lithography and etching steps. For example, waveguide 220 may be deposited, patterned, and etched simultaneously with the formation of silicon gate electrodes during a CMOS IC process.

In applications where post geometries are deep sub-micron, posts 206-211 may be formed by E-beam lithography writing the desired pattern into a photoresist layer deposited on the top of the waveguide 220. Once the photoresist is developed, reactive ion etching can be used to create desired structures within the waveguiding region. The next step involves filling in the holes that have been etched away in the waveguiding region with the appropriate post material to create the SWG structure. A deposition process such as LPCVD or PECVD may be used for this purpose. Finally, a polishing step, such as chemical mechanical polishing (CMP) to improve surface flatness and to eliminate any surface irregularities caused during the process may be added to reduce the lossiness of the cavity. Thus, the very small size, simple structure and standard processing steps involved in forming SWG 205 permit fabrication on a bulk substrate material die and integration with other optical or electronic components on the same die. The particular manufacturing process used for fabricating the grating is not essential to the present invention.

Thus, the invention can a utilize a pair of SWGs, a pair of PCs, or one PC and one SWG to function as a pair of highly reflective mirrors to bound a laser cavity. As used herein, a broadband mirror refers to a mirror which is highly reflective over a range of about at least 3% of the center wavelength of the mirror, preferably 5%, and more preferably 10%. Referring again to FIG. 1(b), PC 100 provides a reflective bandwidth (bandgap 140) of about 140 nm, with a center wavelength of about 1.560 μm. Thus, PC 100 is a broadband mirror as it is highly reflective over a range of about 9% of its center wavelength.

The lasing wavelength of a laser cavity is determined by the resonance condition of the cavity, where the optical path length (OPL) of the cavity is an integral number (M) of half. wavelengths (λ/2), where λ is the resonance (lasing) wavelength. But since a laser cavity can in general have many resonances (due to the M integer term, e.g. M=1, 2, 3 . . . ), there are clearly other factors that specify the laser wavelength. If the mirrors are broadband, then the laser wavelength is simply determined by which resonance wavelength has the greatest gain within the gain curve of the laser.

Narrowband mirrors can still be used with the invention. However, if the mirrors are narrowband, it is more difficult to get lasing action since the narrow reflectance of the mirror must substantially coincide with the peak of the gain curve band of the laser and at least one cavity resonance wavelength to produce lasing.

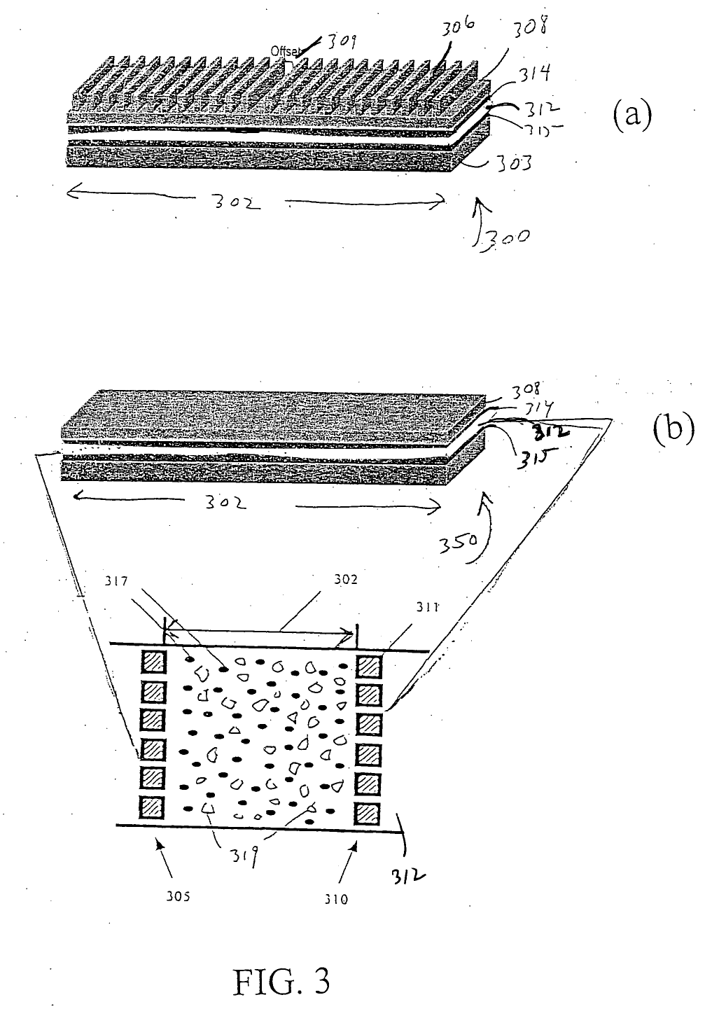

FIG. 3(a) shows a top view of an exemplary solid state laser 300 including a laser cavity 302 which comprises a support layer 303 and a waveguide 312 sandwiched between a pair of electrode layers 314 and 315. Together with a suitable power supply, such as together with an RF oscillator (not shown), electrode layers 314 and 315 provide electronically pumping for laser 300. Although laser 300 is electronically pumped, optical pumping can also be used (not shown).

Support layer 303 is disposed on a bulk silicon substrate (not shown), such as provided by a semiconducting wafer. The support layer 303 functions as a cladding layer. The support layer is preferably selected from CMOS compatible materials, such as a layer of silicon dioxide. A low relative refractive index for the support layer as compared to the optical waveguide material permits the optical waveguide 312 to act as a substantially lossless waveguide and the support layer to act as a suitable cladding layer.

Waveguide 312 is preferably formed from silicon dioxide. Alternatively, waveguide 312 can be formed from an electro-optic (EO) material for electronically tuning the cavity resonance. Electrode layers 314 and 315 can be continuous layers. Waveguide 312 is generally about 300 nm to 1 μm in thickness.

Optically active regions thicker than 1 μm may also be used with the invention. However, there may be a practical problem with thick optically active regions as it becomes more difficult to fabricate the laser cavity with thicknesses of much more than about 1 μm. At a laser cavity thickness of approximately 10 μm, for example, the optical mode structure of the laser beam can begin to change from single mode (TEM₀₀) operation which is very desirable to a combination of modes, which is generally undesirable.

A distributed feedback structure (DFB) 308 which functions as a reflective mirror is disposed on electrode layer 314 and defines the dimension of the laser cavity 302. DFB includes a plurality of etched features 306 which defines grooves therebetween having a periodicity of λ/2n, where λ is the photon wavelength in free space and n is the refractive index of the layer comprising DFB 308.

A DFB based cavity laser 300 is generally simpler to fabricate as compared to cavity lasers which include subwavelength resonant gratings and/or photonic crystals, since DFBs can be formed by simply etching a plurality of grooves in a single layer. A unique feature of a distributed feedback structure (DFB) is it produces an effective mirror reflectance without having actual mirrors. As a wave propagates through the waveguide it encounters the subwavelength grating provided by the DFB. During each cycle of the grating a small amount of light energy is coherently reflected constructively backward. This can be a very small amount of reflection for each period. But if enough periods are provided, virtually all the light will get reflected back toward the center of the structure (i.e. a mirror). At the center of laser cavity 312 the periodicity is offset slightly, such as quarter optical wave offset 309. This causes the distributed reflectances to channel light toward the center of laser cavity 312 from both directions and gives the effect of having a two mirror laser cavity.

By having an offset, such as the quarter optical wave offset 309, the structure is forced to act as two distributed mirrors which creates a distributed laser cavity, where the cavity and mirrors are distributed throughout the entire etched groove region. Although grooves defined by features 306 are shown as having linear dimensions, grooves can also be curved (not shown).

A significant advantage of a DFB structure is that a single spectral mode can be provided without the occurrence of mode hopping. The spatial modes are determined by the channel waveguide physical characteristics, which can easily be configured for single mode operation. Disadvantage of DFB laser 300 include it generally requires many periods (e.g. over 100) to produce a substantial cavity Q factor. In addition, the precision placement of grooves is needed over a large number of periods for proper phasing. Accordingly, formation of a practical laser 300 may require specialized lithography equipment, such as interference optical lithography to pattern the plurality of grooves.

While typically conductors such as electrode layer 314 shield EM radiation, there is a frequency dependence associated with any EM radiation being absorbed. The EM field generated by photons in laser cavity 302 have a frequency of typically around 10¹⁴ Hz. At these frequencies many materials generally regarded as electrical conductors are no longer electrically conductive. Thus, conductors such as indium-tin-oxide (ITO) are virtually clear to most useful optical wavelengths.

Waveguide 312 includes a plurality of randomly distributed semiconducting atoms or molecules, such as Si nanocrystals and an RE species which together function as gain media for laser 300. Semiconducting atoms or compounds non-radiatively transfer energy obtained from the electronic pumping to the RE, permitting the laser to laze, thus increasing the RE optical gain. When the RE is Er, suitably dimensioned laser 300 lases at, or near 1.54 μm. When the RE is holmium, a suitably dimensioned laser 300 lases at from 2.06 to 2.10 microns.

Although electrode layers 314 and 315 are shown disposed above and below waveguide 312, a pair of electrode layers can be disposed on both sides of the resonant cavity (not shown). When laser 300 is electronically pumped and the electrodes are spaced far enough away from the gain region, conventional metal electrodes can be used, such as Al.

When an EO material is used as the waveguide material, in general a single set of electrodes could be used to both pump the gain material and tune the cavity resonance. However, the EO material is generally a crystalline material that requires a specific electric field orientation. For a specific EO material to produce a significant shift in resonance, the applied electric field must be aligned with a certain relationship to the crystal lattice, the orientation used being dependant on the specific EO material used.

FIG. 3(b) shows a laser 350 similar to laser 300 except DBR 308 is replaced by a pair of subwavelength mirrors. Subwavelength mirrors can comprise photonic crystal (PC), a quarter-wave stack, and a subwavelength grating. The subwavelength mirrors shown in FIG. 3(b) comprise subwavelength grating (SWG) mirrors 305 and 310 embedded within optical waveguide material 312 as shown in the inset below FIG. 3(b). The first and second SWG 305 and 310 each comprise a plurality of periodic high refractive index posts 311 which together with the optical waveguide 312 form a Fabry-Perot waveguide laser cavity. Waveguide 312 includes a plurality of semiconducting atoms or molecules such as Si nanocrystals 317 as well as RE such as Er 319. The periodic line of posts comprising the SWGs 305 and 310 are embedded perpendicular to the direction of light propagation and have a periodicity less than the cavity resonance wavelength (subwavelength).

Laser 300 and laser 350 is believed to operate as follows. The semiconducting atoms or molecules such as nanocrystals 317 are coupled with RE atoms or ions 319 in the waveguide material, such as silicon dioxide. Energy provided by the structure for pumping creates hole-electron pairs in the semiconducting atoms or compounds. Recombination of electron-hole pairs in the nanocrystals causes excitation of the RE ions 319, which then emit light. The frequency of the emitted light depends on the choice of RE-earth dopant, such as 1.54 microns for Er.

Since the ends of the laser cavity consist of DBR 308 shown in FIG. 3(a) or a pair of mirrors such as SWG 305 and 310 shown in FIG. 3(b) which function as reflective mirrors, it is expected that any incident light would simply be reflected. That is what happens unless the incident wavelength matches the resonance of cavity 302. At this wavelength (there may be more that one) the incident light goes into the cavity 302 resulting in a large energy density buildup within the cavity 302.

The laser cavity reaches an equilibrium when all the incident light enters the cavity 302 and the same amount exits the other end of the cavity 302. This creates a Fabry-Perot resonator which is the essence of a high Q laser cavity. The amount of energy trapped in the cavity as a function of incident power is a measure of the Q of the laser cavity and is determined by the reflectivity of the cavity mirrors (308, or 305 and 310). The higher the Q of the cavity, the smaller the gain needs to be for lasing to occur. Assuming only a relatively modest amount of gain can be achieved, the cavity 302 should accordingly be designed to be a high Q cavity.

Semiconducting atoms or molecules preferably comprise nanocrystals which are clumps of atoms or molecules, such as silicon atoms. These atoms or molecules can be introduced into the laser cavity region by any suitable technique. For example, ion implantation can be used to introduce atomic or molecular ions, which can be rendered crystalline by a suitable high temperature annealing cycle. In the case of Si, the high temperature anneal coalesces the Si atoms into Si nanocrystals. Typical silicon nanocrystals have diameters of less than about 10 nanometers. The embedded nanocrystals are sometimes referred to as quantum dots.

The physics and optics of certain nanocrystals have been studied quite extensively. Among the many properties that change, the most remarkable is the dramatic change in the optical properties of the nanocrystal as a function of its size. As the size of the nanocrystal decreases, the electronic excitations shift to higher energies (lower wavelengths) due to quantum confinement effects, leading the observed changes in the optical properties. The physical size of nanocrystals begins to have an effect on the optical properties around 10 nm for silicon nanocrystals, but will vary for other nanocrystal materials.

For nanocrystals below about 10 nm in size, it is well known that the emission becomes a function of their size. The emissions can also be controlled with the use of different morphologies for the nanocrystal. For example, a composite nanoparticle can comprise a core made from one nanocrystal material coated with a shell of a second material. In one embodiment, the outer layers of Si nanocrystals can be oxidized.

The nanocrystals introduced into the optical waveguide have physical properties, such as size or composition, that, when excited (i.e. pumped), transfer their excited energy to the RE atoms which in turn emit light (typically in the IR regime) at the laser cavity resonant wavelength. Nanocrystals, such as silicon nanocrystals embedded in erbium doped silicon dioxide with diameters less than 5 nm have been shown to transfer their excess (pumped) energy the dopant erbium atoms. This provides a way of indirectly pumping the erbium atoms via the excitation of silicon nanocrystals. Although SiO₂ has generally been used as the optical waveguide material to form the laser, the invention is in no way limited to SiO₂.

There are several known alternative nanocrystal materials to Si nanocrystals which have been shown to photoluminesce in SiO₂ and are thus candidates for indirect pumping of RE dopants. For example, it is known that Ge luminesces in SiO₂. For example Y. Maeda, Phys. Rev. B 51 (1995) 1658, or K. S. Min et al, Appl. Phys. Lett 68 (1996) 2511 report Ge luminescencing in SiO₂. GaAs is also known to luminesce in SiO₂. Other nanocrystal materials that have been demonstrated to be candidate materials, including the semiconducting compounds CdSe or ZnS.

However, a significant advantage with using silicon nanocrystals is its clear compatibility with standard (CMOS) microelectronics fabrication. A silicon based cavity laser also allows the potential for creating large numbers of NOW lasers on the same chip as well as associated electronics if desired. Thus, the invention allows for the integration of solid-state micro-lasers with semiconductor microchips on a common bulk substrate material. This integration of lasers with semiconductor microchips is made possible because the invention can be generally formed using CMOS compatible materials and processes.

Preferably, when optically pumped the semiconducting nanocrystals provide a broad gain curve, such as 50 nm full width half max (FWHM) to allow optical gain to occur at any wavelength within this 50 nm region. It has been found for silicon nanocrystals that the approximately 50 nm optical gain region can be positioned by adjusting the silicon nanocrystal diameter. REs, such as erbium have very small and narrow gain curves. In addition REs such as erbium, can not be electronically pumped directly. But, nanocrystals, such as silicon nanocrystals, provide a way of indirectly pumping the RE atoms. The nanocrystals can be optically or electronically pumped. They effectively increase the amplitude of the gain curve by being pumped over a wide range of wavelengths which then transfer their energies to the RE atoms. While the resultant RE gain curve is still generally narrow, its amplitude becomes much larger. Thus, by the use of indirect electronic pumping, it becomes much more practical to integrate a laser into a small package or chip.

In an optical waveguide material comprising SiO₂, Si nanocrystals can increase the refractive index of the SiO₂ region in which the embedded nanocrystals are present from about 1.5 to 1.75. At an index of refraction of 1.75, SiO₂ including Si nanocrystals form a waveguiding region as compared to a SiO₂ layer (n_{f} about 1.5). Thus, SiO₂ can be used as a support/cladding layer when disposed in contact with an optical cavity comprising SiO₂ and a plurality of embedded Si nanocrystals.

Alternative optical waveguiding materials other than SiO₂ can accommodate the semiconducting nanocrystals. Another possible alternative waveguide is a form of SiO₂ referred to as an aerogel. Aerogels are exceedingly porous, being about 99.8% air. Silicon nitride (SiₓN_{y}) and solgels may also be used as optical waveguide materials.

Exemplary dimensions for laser 300 shown in FIG. 3 include a resonator length of about 1 μm to a maximum of 100's of μm. A nominal resonator length is about 10 μm. If subwavelength resonant gratings are used as mirrors, such as SWGs 305 and 310 shown in FIG. 3(b), the post size of the gratings can be from 0.1 μm to 0.5 μm diameter thickness. The posts must generally span the entire thickness of the waveguide, generally being embedded in the waveguide structure. For example, for a 1 μm thick active waveguide, the posts should also be about 1 μm long. A nominal post diameter is 0.50 μm. Although the posts shown in FIG. 3 are square (pegs), posts can be a variety of shapes including round (cylinders).

Post spacing requires a subwavelength, or at least close to a subwavelength periodicity. Accordingly, a periodicity of 0.60 μm to 1.40 μm could be used with a 50% fill factor. The thickness of the optical waveguide could be as thin as about 1 μm, or less, or as thick as about 1 mm. However, the thicker the waveguide is the more difficult it is to make the posts as the posts must generally extend throughout the thickness of the active waveguide region. There are also some other practical factors, such as single mode operation, that usually favor use of a thin waveguide.

The posts should have a substantially larger relative refractive index than the waveguide cavity material and be non-absorbing (a dielectric) at the lasing wavelength. If standard SiO₂ (n_{f} of about 1.5) is used as the laser cavity matrix material, suitable standard optical materials which could be used for posts, including Ta₂O₅, TiO₂, ZnO, and ZnSe. If other lower refractive index laser cavity matrix materials are used, such as aerogel which has an n_{f} of about 1.01, almost any non-absorbing dielectric material could be used to form the posts.

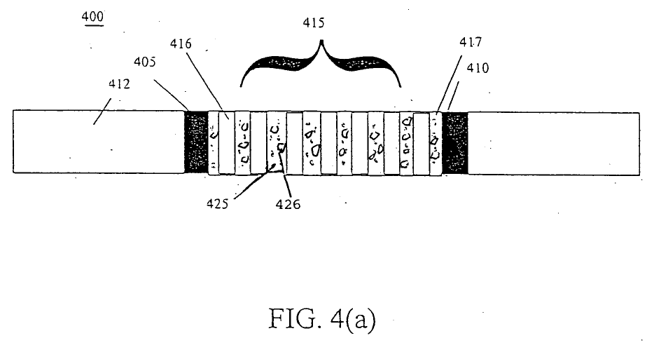

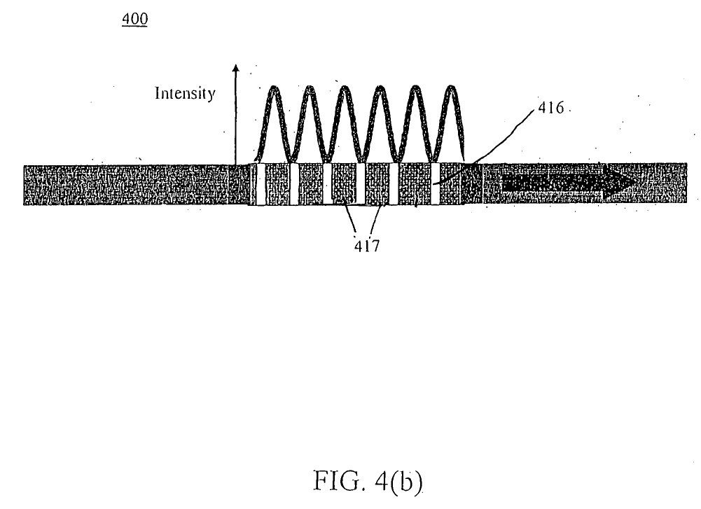

In another embodiment of the invention shown in FIG. 4, a cross-sectional view of a SNEW laser 400 is which includes photonic band edge structure (PBE) 415 comprising a photonic crystal (PC). Laser 400 includes first and second SWG 405 and 410 mirrors and a PBE 415 formed in the optical waveguide 412 of laser 400 between mirrors 405 and 410. A plurality of randomly distributed nanocrystals 425 and RE species 426 and are disposed in optical waveguide 412 between SWG mirrors 405 and 410. An optical pump, such as an external Ar laser (not shown), or an electronic pump comprises an electrode pair sandwiching waveguide 412 (not shown), can be used to provide pumping for laser 400.

SWG mirrors 405 and 410 comprise a plurality of high refractive index periodic features (not shown) relative to the refractive index of waveguide 412, SWG 405 and 410 are designed to provide a broadband reflective response. The broadband reflective range includes the desired operating wavelength of laser 400, which is generally a single wavelength.

PBE 415 is a photonic crystal (PC) which is disposed in the lasing cavity and includes a periodic array of low index features, such as holes 416. As noted relative to FIG. 1(b), PC 100 provides both a band gap 140, as well as an air band edge 144 and a dielectric band edge 148. PBE 415 can be etched in the waveguide material 412. PBE holes can be unfilled, or filled with a low relative refractive index material, such as virtually any type of gas, including air.

If laser's 400 normal lasing wavelength is within the PBE's 415 band gap (forbidden) region, no energy will be allowed to propagate within the cavity and no lasing would occur. However, if the laser is operated at a wavelength at which PBE 415 is substantially transmissive, such as at its band edge regions, lasing can occur. Preferably, PBE 415 provides a dielectric band edge which permits PBE 415 to provide substantial transmission at an operating wavelength of laser 400. As used herein, substantial transmission by PBE 415 is defined as at least 80% , and preferably 100% transmission.

The plurality of periodic cavity holes 415 are preferably provided with a periodicity which results in a dielectric band edge which coincides closely with the operating wavelength of the laser. Thus, laser 400 can operate at a wavelength that meets the conditions of being at (or near) the peak of the nanocrystal photoluminescence gain curve, being well within the broadband reflective response of SWG mirrors 405 and 410, as well as closely coinciding with the dielectric band edge wavelength of the PBE 415.

If laser 400 is operated at (or near) the dielectric band edge, such as 148 in FIG. 1(b), energy is concentrated in the high index dielectric waveguide material 412 in which nanocrystals 425 and RE species 426 are disposed. Disposed between mirrors 405 and 410 by operating at the dielectric band edge of the PBE 415, the mode structure is forced to be single mode (TEM₀₀) while still having the energy concentrated in the nanocrystal material. Thus, laser 400 operated at the dielectric band edge of PBE 415 forces the cavity electromagnetic standing waves to have a single spatial and frequency mode. This dramatically improves the coherence and overall efficiency of laser 400 as the combined periodicities of the mirror features, such as, high index posts of the SWGs 405 and 410, and the low index PBE holes 416 result in a mode and phase lock of the emission by laser 400. Since semiconducting nanocrystals 425 and RE species 426 both reside and are concentrated within the resulting intensified electromagnetic field, the result is an enhancement to the laser gain, thus increasing the output power of laser 400.

FIG. 4(b) shows the energy distribution operation of laser 400 operated at a dielectric band edge wavelength. Operation at the dielectric band edge forces the TEM₀₀ laser mode and can be seen to concentrate energy away from the holes 416 and toward the high dielectric waveguide regions 417 in the laser cavity which includes the plurality of semiconducting nanocrystals and RE atoms (not shown). Accordingly, laser 400 including PBE 415 can significantly enhance the mode structure, coherence, efficiency and overall performance of laser 400.

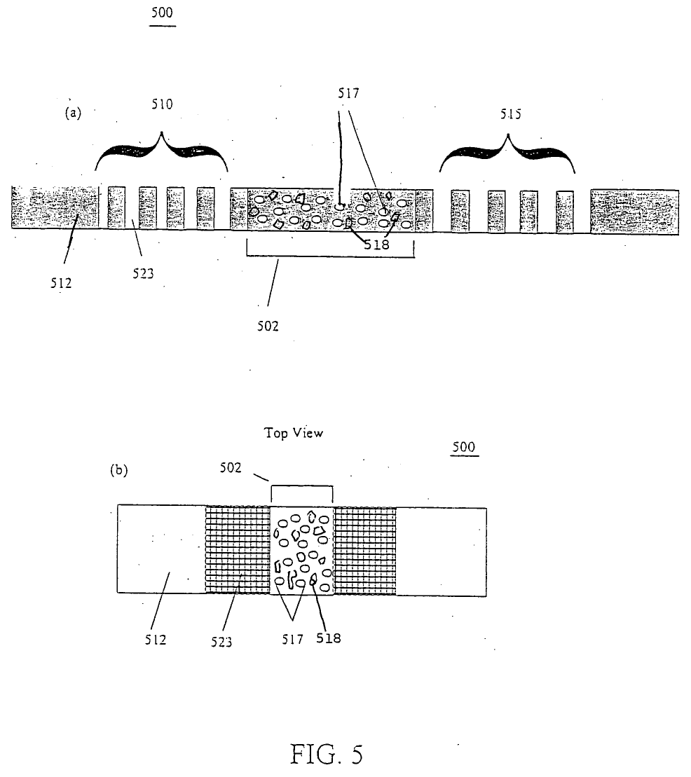

FIG. 5(a) shows a cross-section view while FIG. 5(b) shows a top view of a laser 500 which includes a pair of subwavelength mirrors 510 and 515 each formed from PCs. Each PC includes a plurality of periodically spaced low refractive index features, such as holes 523 formed in optical waveguide material 512. Laser 500 includes a laser cavity 502 which comprises a waveguide material 512 including a plurality of semiconducting nanocrystals 517 and RE species 518.

In another embodiment of the invention, a symmetric waveguide laser cavity can be formed. For example, by adding an additional thin film, such as a few microns or less of SiO₂ on top of the waveguide region which includes the semiconducting nanocrystals and RE species, a symmetrical waveguide cavity can be formed.

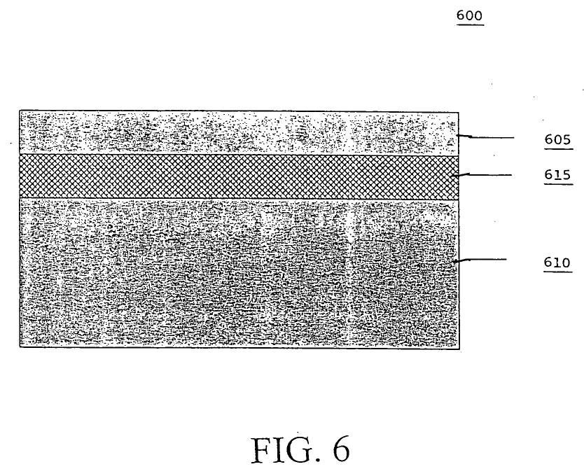

For example, FIG. 6 shows a symmetrical optical waveguide structure 600 formed using a top layer 605 and bottom layer 610 of a particular cladding material to sandwich a layer of waveguiding material 615 having embedded semiconducting nanocrystals and RE species (not shown). Although it is preferred to have top 605 and bottom layer 610 to be formed from the same material, different materials having near equal indexes of refraction may also be used for top layer 605 and bottom layer 610.

A major advantage of forming a symmetrical waveguide structure is that at least one optical mode will always exist within the waveguide. The symmetrical nature of optical waveguide structure 600 having the same top and bottom cladding layer surrounding the thin film waveguide means that the energy will be symmetrically distributed in the waveguide. This is referred to as a symmetric mode. In symmetric waveguides there is always at least one confined mode. Single mode performance is generally achieved by selecting a relatively thin waveguide material, such as about 1 μm for most waveguide materials.

If the waveguide is asymmetrical, it is possible that the waveguide will not support any transmission. In addition, the energy leakage from the symmetric waveguide is minimized relative to an asymmetric structure. Finally, the dominate mode in a symmetric waveguide is generally desired TEM₀₀ mode, which consists of a Gaussian wave front.

Nanocrystals can be produced having sizes virtually anywhere in the nm range. To produce silicon nanocrystals, for example ion implantation has been successfully used. Silicon ions can be implanted into a RE doped thin film of silicon dioxide (glass). Silicon is generally implanted at room temperature, although other temperatures can be used as well. The starting implanted Si concentration significantly influences the size and the properties of the nanoparticles which are formed after annealing. At a sufficiently low enough implanted dose, Si dissolves in the substrate and no Si nanoparticles particles are formed. It is estimated that a minimum concentration to form Si nanocrystals is about 5.0×10²⁰/cm³.

Annealing forces the embedded silicon atoms to coalesce into silicon nanocrystals. The size of the nanoparticles depends on processing conditions. Annealing should generally be performed at 1000° C. or more, such as 1100° C. which has generally been used. A 1100° C. anneal has been performed for 1 hr, but Si nanocrystal to RE energy coupling is possible for shorter or longer anneal times. The energy coupling is generally a function of the anneal time. It generally reaches a maximum after a short time, then monotonically decreases with anneal time. Intense energy coupling has been observed using particles 1 to 5 nm in diameter.

To produce a uniform distribution (matrix) of atoms throughout the thickness of the cavity waveguide material, such as SiO₂, multiple ion energies can be used during implantation to adjust the implantation depth. Once a fairly uniform distribution of silicon atoms has been implanted, the film is then preferably annealed.

It is believed that the amount of energy coupled from the Si nanocrystals to the RE is dependent on particle size. The Si nanoparticles generally grow in size with annealing.

If the SiO₂ has not been previously doped with RE species such as Er, the RE species can be introduced using ion implantation at room temperature. Other methods for introduction of REs may also be possible.

Lasers according to the invention can also be wavelength tunable. For example, the laser wavelength is based on both the size of the nanocrystals and on the laser cavity architecture, both of which can be designed for a given lasing wavelength. The laser may be customized for laser wavelengths over a fairly broad wavelength range, such as from 0.6 μm to 2.6 μm.

The laser can be dynamically wavelength tunable as well. This embodiment allows the laser to be electronically tuned to a specific wavelength based on the applied voltage. If the laser cavity is comprised of an electro-optic waveguide material, such as SBN, CdTe and LiNbO₃, and if the waveguide material separating reflective mirrors is positioned between two electrodes, the cavity's optical path length can be varied by application of a voltage across the electrodes. Electro-optic materials are materials that have refractive indices that can be altered by application of an electric field. Since the cavity's optical path length (OPL) is a function of the physical grating separation distance (d) multiplied by the waveguide's index of refraction (n), a change in the waveguide's index of refraction shifts the optical path length. A change in the cavity's optical path length shifts the center resonant wavelength an amount Δλ:

Δλ=(2d(Δₙ))/m, where m is possible cavity modes=1,2,3 . . . . For a single mode cavity, Δλ=2d(Δn).

The term cavity mode in this context is different than the modes discussed earlier. Cavity mode refers to a wavelength mode, where as the modes previously discussed have been spatial modes of energy distribution from a particular wavelength.

Application of a voltage across an electro-optic cavity having a Q significantly greater than 1 causes an electro-optic amplification effect because of the electromagnetic wave reflections within the cavity. The electro-optic effect amplification allows a beam of photons to be modulated with a correspondingly lower applied voltage due to a lengthened residence time in the laser cavity. For example, an electro-optic cavity having a Q of 500 allows a voltage equal to 1/500 of the voltage otherwise required to modulate an electro-optic cavity having a Q equal to 1. Thus, a low voltage optical modulator may be realized which allows higher switching speeds and compatibility with state of the art integrated circuits which use very low power supply voltages, such as 10 volts, or less.

It is estimated that by adding electrodes and using an electro-optic waveguide material instead of SiO₂ (glass), the resulting laser could be tunable over tens of nanometers of wavelength. A routing experimentation can be used to identify alternative waveguide materials to SiO₂ that allows the silicon nanocrystals to produce enough photoluminescence to function as an optical gain media.

Pumping the active media can be provided by any suitable technique. For example, electrodes could be used to supply electrical pumping to the active gain media.

The laser can be operated as laser/modulator. For example, the laser can be indirectly modulated. That is, if the pumping energy, such as UV light, were to be amplitude or frequency modulated, then the laser output intensity could be correspondingly modulated.

This invention has a broad range of possible uses and applications. In one embodiment the invention is used as an amplifier on a communications chip. Such an amplifier version is a simpler structure as compared to laser 300. For example, an erbium doped optical amplifier (EDOA) is simply a short (˜<1 meter) optically pumped fiber, or channel waveguide, ridge waveguide, or even a planar waveguide, that has been doped with erbium (generally doped from 0.2% to 5% erbium). In the simplest embodiment, nanocrystals would be used to dope waveguide section, thus increasing the existing optical gain and make the amplifier more efficient. The next embodiment would additionally change the optical pump wavelength from IR to a broad UV set of wavelengths. For example, Si nanocystals have the ability to absorb a broad range of UV wavelengths and transfer this absorbed energy to the Er. This would change the amplifier pumping characteristics and would potentially increase the amplifier gain even more. A third amplifier embodiment would replace the optical pumping with electronic pumping. This would be the most dramatic change of all, in that the current erbium doped optical amplifier would go from a large optical device to a very small device. Currently, EDOA optical pumping requires a large flash lamp to pump (activate) the Er.

The invention can dispose multiple laser sources on a CMOS chip to form new types of micro optical sensors and detectors. Lasers according to the invention could be made small enough and compatible (with CMOS processing) to have arrays of lasers embedded on a chip. The amount of laser power produced by each laser would be very small (since power scales with size), but the normal laser and waveguide coupling losses would be minimal. Such and array could be used to probe various biological and chemical species applied and detected at the chip level. And since this would be done on a CMOS chip, all the associated control and logic electronics would be available on the same chip, making a unique chip level sensor system.

The ability to integrate lasers into semiconductor microchips can lead to practical optical computers, integrated optical interconnects, and new integrated optical modulators. By coupling a second laser cavity (sensor) to the SNEW laser cavity, laser radiation could be nominally passed through the second structure, assuming that both cavities are tuned to the same wavelength. If a chemical or biological agent is then passed through the sensor part via PC holes within the sensor cavity, the sensor cavity will modify the intensity of the transmitted beam based on the composition of the agent or chemical. By making an array of such laser and sensor cavities, each tuned to a slightly different wavelength, and by monitoring the composite transmission from these arrays, an extremely sensitive and accurate chemical and biological detector device can be configured.

Optical computing can become practical with the small embedded laser sources described herein. Each laser source can effectively be a digital input variable. The creation of integrated optical gates has been established researchers of many years. The problem with optical computing is not with creating logic gates, but is with generating integrated optical sources. This invention solves this problem by providing the required integrated optical sources.

Integrated optical interconnects can also be formed using the invention. Again the problem with using optical interconnects is one of creating, transmitting, and detecting modulated optical sources. Lasers according to the invention can provide integrated light sources internal to the microchip. Modulation of these sources can be accomplished in a variety of ways, such as direct laser modulation through electronic pumping, Q switching via the use of photonic band edge holes within the cavity, or by modulation of the mirror reflectance using EO materials to make PC mirrors.

While the preferred embodiments of the invention have been illustrated and described, it will be clear that the invention is not so limited. Numerous modifications, changes, variations, substitutions and equivalents will occur to those skilled in the art without departing from the spirit and scope of the present invention as described in the claims.

What is claimed is:

1. A rare earth-doped solid-state integrated laser, comprising:
an optical waveguide;
a laser cavity including at least one subwavelength mirror, said subwavelength mirror disposed in or on said optical waveguide, said optical waveguide within said laser cavity including active media comprising both rare earth and semiconducting atoms or compounds, and
a structure for pumping said semiconducting atoms or compounds, wherein said semiconducting atoms or compounds transfer energy obtained from said pumping to said rare earth, said rare earth emitting light.

2. The laser of claim 1, wherein said structure for pumping comprises a pair of electrodes sandwiching said active media.

3. The laser of claim 1, wherein said rare earth comprises Er and said laser cavity is resonant at from 1.52 to 1.57 microns.

4. The laser of claim 1, wherein said subwavelength mirror comprises a first and a second subwavelength mirror, said first and second subwavelength mirror disposed on respective ends of said laser cavity.

5. The laser of claim 4, wherein said first and second subwavelength mirrors comprise subwavelength resonant gratings, each said grating comprising a plurality of periodically spaced high refractive index features disposed in said waveguide, said high refractive index features providing a refractive index higher than a refractive index of said optical waveguide.

6. The laser of claim 4, wherein said first and second subwavelength mirrors comprise photonic crystals, each said photonic crystal having a plurality of low refractive index features in said waveguide, said low refractive index lower than a refractive index of said optical waveguide.

7. The laser of claim 1, wherein said at least one subwavelength mirror comprises a distributed feedback structure (DFB), wherein light in said laser cavity is channeled toward a center of said laser cavity.

8. The laser of claim 1, wherein said optical waveguide comprises silicon dioxide.

9. The laser of claim 4, further comprising a photonic band edge structure (PBE) positioned between said first and a second subwavelength mirrors.

10. The laser of claim 1, wherein said semiconducting atoms or compounds comprise silicon nanocrystals.

11. The laser of claim 1, said laser is disposed on or embedded in a bulk substrate material.

12. The laser of claim 1, wherein said optical waveguide comprises an electro-optic material.

13. A method for forming a rare earth-doped solid-state integrated laser, comprising the steps of:
providing an optical waveguide;
forming a laser cavity including at least one reflective subwavelength mirror disposed in or on said optical waveguide, and
positioning a plurality of rare earth and semiconducting atoms or compounds in said laser cavity.

14. The method of claim 13, further comprising the step of forming a pair of electrodes, said electrodes sandwiching said rare earth and semiconducting atoms or compounds in said laser cavity.

15. The method of claim 13, wherein said rare earth comprises Er and said laser cavity is resonant from 1.52 to 1.57 microns.

16. The method of claim 13, wherein said semiconducting atoms or compounds comprise a plurality of nanocrystals, further comprising the step of forming said plurality of nanocrystals.

17. The method of claim 16, wherein said nanocrystals are Si nanocrystals.

18. The method of claim 13, wherein said at least one subwavelength mirror comprises a first and a second subwavelength mirror, said first and second subwavelength mirror disposed on respective ends of said laser cavity.

19. The method of claim 13, wherein said optical waveguide comprises silicon dioxide.

20. The method of claim 13, wherein said optical waveguide comprises an electro-optic material.
